(19) United States
(12) Patent Application Publication
(10) Pub. No.: US 2001/0026840 A1
(43) Pub. Date: Oct. 4, 2001

(54) Method of metalizing a semiconductor power device ceramic member

(76) Inventors: Burhan Ozmat, Voorheesville, NY (US); Victor A. K. Temple, Clifton, NY (US); James R. Murray SR., Corinth, NY (US)

Correspondence Address: JAECKLE FLEISCHMANN & MUGEL, LLP, Suite 200, 39 State Street, Rochester, NY, 14614-1310, US

(21) Appl. No.: 09/792,672

(22) Filed: Feb. 23, 2001

Related U.S. Application Data
(63) Continuation of application No. 08/759,865, filed on Dec. 8, 1996.

(51) Int. Cl. C23C 16/00; H01L 21/44

(52) U.S. Cl. 427/250; 438/106; 438/680; 438/763

(57) ABSTRACT

A method of metalizing a ceramic member (e.g., lid or thermal base) for a semiconductor power device with a film of aluminum in an ion vapor deposition chamber in which an argon ion cloud is formed around the member within the chamber by biasing the member with a voltage and in which a continuous source of aluminum vapor is provided within the chamber so that aluminum ions are available to be accelerated towards the member from plural directions by the bias voltage, the aluminum ions being formed from the aluminum vapor upon passage through the argon ion cloud. The member may be an array of plates that are metalized before being separated. The metalized plates may be used as lids for semiconductor device packages or as thermal bases for power modules.

### CROSS-REFERENCE TO RELATED APPLICATION

This application is a continuation of U.S. patent application Ser. No. 08/759,865, filed Dec. 3, 1996.

### BACKGROUND OF THE INVENTION

The present invention relates to method of metalizing a ceramic, glass or glass ceramic member, and more particularly to a method of depositing an aluminum film onto a ceramic member for a semiconductor power device using an inert gas-filled ion vapor deposition chamber having a continuous source of aluminum vapor within the chamber.

Microelectronic packages of discrete semiconductor power devices and power modules having multiple semiconductor power devices include ceramic members that are coated with a thin metal film. The metal film may be etched, as when the metalized ceramic member is a lid for semiconductor device package with patterned metal on its top and bottom and through holes, or the metal film may be continuous, as when the metalized ceramic member is a thermal base for a module of several power devices. The performance of the semiconductor power devices depend, at least in part, on the characteristics of these metalized ceramic members and the present invention is directed to improving the cost, yield and reliability of metalized ceramic members.

One of the problems of the prior art is the metal-to-ceramic adhesion of the metal film which is typically several thousandths of an inch thick. The adhesion may not be uniform, and may not be sufficient. For example, a copper coating process in which a ceramic is plated with electroless copper several microns thick and then electroplated with copper to the desired thickness provides an adhesion strength of ceramic to copper as low as a few hundred PSI (as measured by Sebastian pin pull tests) which is generally inadequate for further processing and reliable operation. Further, if the metal is deposited with an ion beam, the thickness of the deposited metal is less likely to be uniform (see, for example, U.S. Pat. No. 4,828,870 to Ando, et al.) Another approach has been direct bond copper (DBC) eutectic bonding for metalizing a lid of power device package. DBC bonding is not compatible with high performance ceramics, such as AIN, which are likely to be preferred in advanced designs. Further, the bonding mechanism requires MXOy stoichiometry which increases manufacturing costs and complexity.

As mentioned above, another component of power packages and modules for which the present invention finds application is a electrically isolating thermal base. Thermal bases are parts of packages for advanced power devices and may be flat plates about 0.010 to 0.100 inches thick which range in size in plane from fractions of an inch to several inches. The core of a thermal base is typically a thermally conducting ceramic, such as AIN, and metalization may be provided over the entire ceramic core (or as much as needed). As depicted in FIG. 1, one or more power device components 10 (e.g., a power switch) may be soldered to the thermal base 12 which is in turn mounted on a platform 14 which may be a heat exchanger or support frame.

The present invention may employ an ion vapor deposition (IVD) process for applying a coat of aluminum. The IVD process has been used to apply a protective coat of aluminum or other metals to parts of an aircraft fuselage and to various structural metals such as steel, but the process has not been used in the semiconductor industry to coat ceramic members for packaging semiconductor devices.

Accordingly, it is an object of the present invention to provide a novel method of metalizing a ceramic member for a semiconductor power device package or module of semiconductor power devices which obviates the problems of the prior art.

It is another object of the present invention to provide a novel method of metalizing a ceramic member in a vacuum chamber in which the member is surrounded with an inert gas ion cloud within the chamber, and a continuous source of metal vapor is provided within the chamber for forming metal ions which simultaneously metalize all exposed surfaces of the member.

It is yet another object of the present invention to provide a novel method of metalizing a ceramic member for a semiconductor power device package or modules of power devices with a film of aluminum in an ion vapor deposition chamber in which the member is surrounded with an argon ion cloud within the chamber by charging the member with a bias voltage, and a continuous source of aluminum vapor is provided within the chamber so that aluminum ions are available to be accelerated towards the member simultaneously from plural directions by the bias voltage, the aluminum ions being formed upon passage of the aluminum vapor through the inert gas ion cloud.

It is still another object of the present invention to provide a novel method of depositing an aluminum film on a ceramic, glass or glass ceramic member by placing the member in an ion vapor deposition chamber, filling the chamber with a cloud of argon, vaporizing aluminum in the chamber, and applying a bias voltage to the member so that the argon is ionized and forms a glow discharge around the member and so that the aluminum vapor is directed toward the member to thereby deposit a film of aluminum on the surfaces of the member.

It is a further object of the present invention to provide a novel method of adhering a stress-relieving metal film to a top and a bottom of a ceramic member for a semiconductor power device package or module in an inert gas-filled ion vapor deposition chamber with vaporized metal therein, in which the inert gas is ionized and forms a glow discharge around the member and so that the metal vapor is directed toward the top and bottom of the member simultaneously and is ionized by passage through the glow discharge to thereby deposit a stress-relieving metal film on the top and bottom of the member.

These and many other objects and advantages of the present invention will be readily apparent to one skilled in the art to which the invention pertains from a perusal of the claims, the appended drawings, and the following detailed description of the preferred embodiments.

### BRIEF DESCRIPTION OF THE DRAWINGS

FIG. 1 is a side view of semiconductor power device of the prior art showing a thermal base between device components and a bottom platform.

FIG. 2 is a top plan view of an array of plural ceramic plates before separation.

FIG. 3A is a top plan view of one plate form the array of FIG. 1 with through holes.

FIG. 3B is a plan view of an exemplary top surface of a metalized plate which has been patterned.

FIG. 3C is a plan view of an exemplary bottom surface of a metalized plate which has been patterned.

FIG. 4A is a vertical cross section of a lid with through holes, indicating a detail shown in FIGS. 4B and 4C.

FIG. 4B is a vertical cross section of the detail indicated in FIG. 4A illustrating metalization by the process of the present invention before patterning.

FIG. 4C is a vertical cross section of the detail indicated in FIG. 4A illustrating metalization by the process of the present invention after initial patterning.

FIG. 5 is a pictorial depiction of a frame fore holding an array of ceramic plates, such as the one illustrated in FIG. 2.

FIG. 6 is a cut-away pictorial depiction of the interior of an ion vapor deposition chamber with a rack of framed arrays and heating crucible therein.

### DESCRIPTION OF PREFERRED EMBODIMENTS

In a preferred embodiment of the present invention, an aluminum film is coated on a ceramic, glass or glass ceramic member by placing the ceramic, glass or glass ceramic member in an ion vapor deposition chamber so that the member's surfaces on which aluminum is to be deposited are exposed, filling the entire chamber with argon to the partial pressure of the argon, providing a continuous source of vaporized aluminum in the chamber, and applying a bias voltage to the member so that the argon is ionized and forms an argon ion cloud (i.e., a glow discharge) around the member and so that the vaporized aluminum is directed toward the member and is ionized by passage through the glow discharge to thereby deposit a film of aluminum on the exposed surfaces of the member. (Hereinafter, the terms “member” and “ceramic member” refer to a ceramic, glass or glass ceramic member.)

The collision of the aluminum and inert gas ions with the aluminum atoms in the vapor as the aluminum and inert gas ions are accelerated toward the negatively biased member creates more aluminum ions. The glow discharge surrounds the member so that the majority of the aluminum ions are created immediately adjacent the member. Thus, the method is not directional so that aluminum is deposited on all exposed surfaces simultaneously.

The aluminum vapor may be provided continuously by providing a source of aluminum wire in the chamber and feeding the aluminum wire from the source to a heating crucible (such as a resistance heated crucible) in the chamber so that the aluminum is vaporized. The bias voltage of one or more thousands of volts (e.g., up to about 4000 volts) may be applied continuously between the member (the cathode) and the anode in the chamber until the aluminum film is the desired thickness, typically between about 50 and 100 microns (e.g., a negative bias of 2000 volts may be applied for about four hours to achieve a preferred thickness of 50 to 75 microns at a deposition rate of better than 50 Å/sec.)

The ceramic member may be an -array of semiconductor device plates, such as lids which may have a plurality of through holes, or thermal bases. The surfaces to be metalized may include the array top and bottom surfaces and interiors of the through holes.

As mentioned above in the Background of the Invention, a power device may include a lid which has patterns of metalization on its top and bottom surfaces. With reference now to FIG. 2, the lids may be fabricated from a sheet of ceramic 20 which has been laser machined and scribed to form an array of lids 22. As shown in FIG. 3A which illustrates one of the lids 22, lid 22 may be provided with through holes 24. The top surface of the lid (FIG. 3B) and bottom surface (FIG. 3C) may be patterned with metal 26 as needed. The pattern may match the pattern of solderable metalization on the semiconductor device. The preferred method of further assembly in which devises, diodes, electrodes and the like are attached is a single or multiple step soldering process using a single alloy or alloys with an appropriate melting point hierarchy. This approach eliminates the need for traditional wire bonding to make contacts to external electrodes and, thus, eliminates wire fatigue and fracturing of brittle semiconductor dies under the stress of wire bonding. The invention herein improves the method of metalizing the lid before it is patterned and, thus, increases the compatibility of the lid with the subsequent processing steps. The metalized lid with through holes that form an electrically conductive path from top to bottom surface offers a very low inductance connection to external electrodes as needed by high current/power advance discrete power packages and modules.

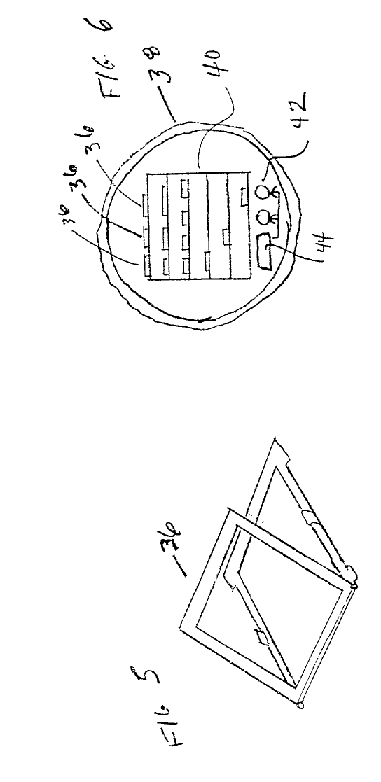

FIGS. 4A-C illustrate a lid 28 in vertical cross-section (FIG. 4A), and show a detail of the metalization 30 of the present invention covering the surfaces of the lid, including the interiors of through holes 32 before subsequent patterning (FIG. 4B) and after a first patterning step (FIG. 4C) toward achieving the pattern of FIG. 3C.

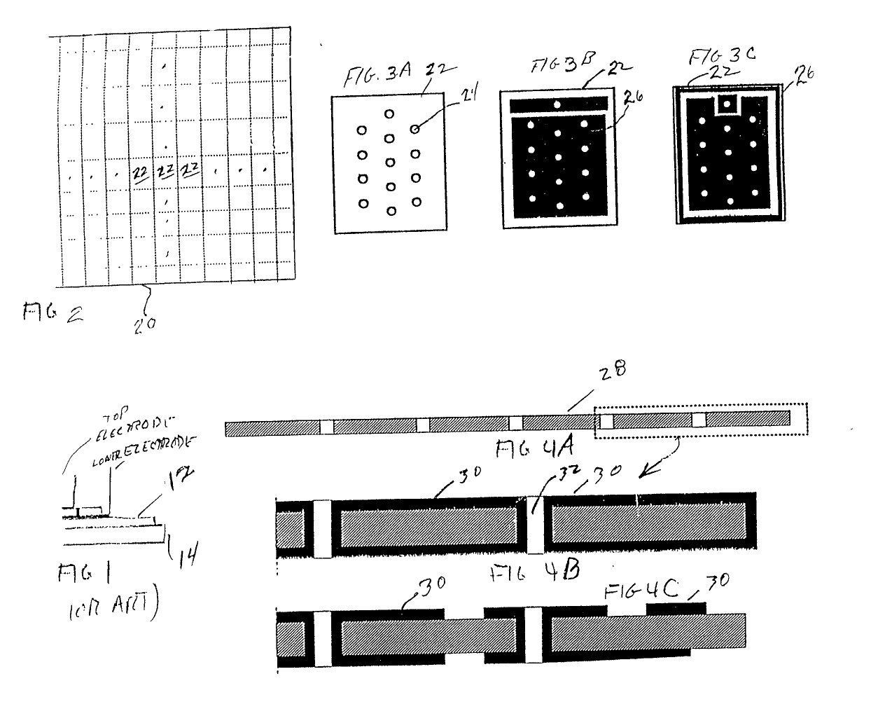

The method of the present invention may also be used to provide a soft and thick aluminum layer of high purity and low modules which acts as a stress-relieving cushion for the brittle ceramic plate at the core of a thermal base. This is a particular advantage for a thermal base used in a power device module such as a power electronic building block (PEBB). As illustrated in FIG. 1, power components are attached to thermal base 12 which is in turn attached to platform 14 which may be a heat exchanger or support frame. Thermal base 12 may be 8 metalized by the process herein and further plated with a nickel coat to form a solderable metalization for attachment of the components. The stress-relieving cushion provided by the aluminum metalization increases reliability of the modules in the face of subsequent handling and assembly related stresses. The two sided aluminum metalization provided herein also facilitates attachment of thermal bases 12 directly to the underlying platform 14 with screws.

The ion vapor deposition of the aluminum on the ceramic member improves the metallic adhesion to several thousand PSI which is high enough to cause the member to fail first in Sebastian pull tests. The member may be cleaned to improve adhesion by sputter cleaning the member in the chamber with an argon plasma before vaporizing the aluminum in the chamber.

The ceramic member may be an appropriate ceramic, glass or glass ceramic, such as alumina, aluminum nitride, beryllium oxide, silicon carbide, and silicon nitride. While the use of argon to form the glow discharge and aluminum to metalize the member is preferred, other appropriate inert gases and metals may be used.

With references now to FIGS. 5 and 6, the process may include placement of an array of the lids or bases (such as in FIG. 2) in a frame 36, and placement of a plurality of the frames 36 in a vacuum chamber such as IVD chamber 38 on a rack 40 with one or more heating crucibles 42 fed from a source of aluminum 44 in the chamber for providing the continuous source of 9 aluminum vapor. Commercially available IVD chambers can accommodate several hundred 4.5″×4.5″×0.025″ ceramic arrays.

The ceramic members made by the method described herein provide advantages in structural reliability and electrical performance for discrete power packages and multiple power device modules which contain high power/high current semiconductor devices. Heretofore, such packages and modules have included multiple bond wires with high inductance and low structural reliability. High reliability, high currents and high switching speeds are required in a myriad of applications (e.g., automotive applications, high power industrial and military motor drives, voltage and frequency converters.) The devices made by the method herein include electrical feed-throughs which may be directly soldered to the matched solderable material pattern in the device to provide reliable, low inductance connections for a variety of semiconductor devices such as IGBTs, MCTs, CMOS devices, and the like.

While preferred embodiments of the present invention have been described, it is to be understood that the embodiments described are illustrative only, and the scope of the invention is to be defined solely by the appended claims when accorded a full range of equivalence, many variations and modifications naturally occurring to those of skill in the art from a perusal hereof.

What is claimed is:

1. A method of depositing a metal on a ceramic component of a package for an integrated circuit comprising the steps of:
(A) providing the ceramic component;
(B) surrounding the ceramic component with an inert gas;
(C) providing metal atoms;
(D) electrically charging the ceramic component to thereby ionize the inert gas;
(E) charging the metal atoms by the presence of the ionized inert gas to thereby form metal ions, and
(F) simultaneously depositing the metal ions on all exposed surfaces of the charged ceramic component.

2. The method of claim 1 wherein the metal is aluminum.

3. The method of claim 1 wherein the ceramic object is an array of semiconductor device ceramic plates each comprising plural surfaces.

4. The method of claim 3 wherein the plates are from the group of lids for semiconductor power device packages and thermal bases for semiconductor power device modules.

5. The method of claim 4 wherein the plates have a plurality of through holes.

6. The method of claim 1 wherein the inert gas is argon.

7. The method of claim 1 wherein the object is electrically charged to a negative bias voltage not greater than approximately 4,000 volts.

8. A ceramic component with an aluminum film made by the process of claim 1.

9. The ceramic component of claim 8 wherein said ceramic component includes an integrated circuit device ceramic plate with top and bottom surfaces and a plurality of through holes, the aluminum film being deposited on said surfaces and the walls of the through holes.

10. A member useful as on of a lid for integrated circuit packages and a thermal base for integrated circuit modules comprising:
a ceramic plate having top and bottom surfaces with a plurality of through holes;
a layer of metal on said top and bottom surfaces and the walls of said through holes, said metal layer being selectively patterned to connect selected areas of said metal layer on said top surface to selected areas of said metal layer on said bottom surface through the metal layer on the walls of said through holes.

11. The member of claim 10 wherein said ceramic is one or more of the group comprising alumina, aluminum oxide, beryllium oxide, silicon carbide and silicon nitride.

12. The member of claim 10 wherein said metal layer is aluminum less than about 100 microns thick.

13. The member of claim 12 wherein said aluminum layer is aluminum between about 50 and 75 microns thick.

14. A method of depositing an aluminum film on a ceramic component of an integrated circuit package with plural surfaces in a vapor deposition chamber comprising the steps of:
(A) providing a vapor deposition-chamber;
(B) placing the ceramic component in the chamber;
(C) drawing a vacuum in the chamber;
(D) filling the chamber with argon to a pressure of a few millitorr;
(E) continuously providing vaporized aluminum in the chamber by feeding aluminum wire to a heating crucible to thereby vaporize the aluminum wire;
(F) forming a glow discharge around the object by primarily applying a negative bias voltage to a frame surrounding the ceramic component an amount of the argon being ionized by the applied negative voltage being sufficient to ionize the vaporized aluminum passing through the glow discharge;
(G) ionizing the vaporized aluminum by passage of the aluminum through the argon by the applied voltage, and
(H) depositing on all of the plural surfaces of the ceramic component the ionized aluminum ions simultaneously from plural directions to thereby deposit the aluminum film uniformly on the ceramic object.

15. The method of claim 14 wherein the ceramic component is an array of integrated circuit ceramic plates each comprising plural surfaces.

16. The method of claim 15 wherein the plates are from the group of lids for integrated circuit device packages and thermal bases for integrated circuit power device modules.

17. The method of claim 16 wherein the plates have a plurality of through holes.

18. The method of claim 14 wherein the negative bias voltage applied to the frame is not greater than 4,000 volts.

19. The method of claim 18 wherein the negative bias voltage is applied until the aluminum film deposited on the ceramic component is 50 to 100 microns thick.

20. The method of claim 14 wherein the deposition rate of the aluminum film on the ceramic component is at least 50 angstroms per second.

21. The method of claim 14 wherein the step of forming the glow discharge includes applying the negative bias voltage of approximately 2,000 volts for approximately four hours so that the aluminum film is deposited at a rate of at least 50 angstroms per second and achieves a thickness of 50 to 75 microns.

22. The method of claim 14 further comprising the step of sputter cleaning the object in situ with argon plasma prior to continually providing vaporized aluminum in the chamber.

23. The method of claim 14 wherein the ceramic component comprises a material selected from the group consisting of alumina, aluminum nitride, beryllium oxide, silicon carbide, and silicon nitride.

24. A method of adhering a metal film to a ceramic component for an integrated circuit package comprising the steps of:
(A) providing a vapor deposition chamber;
(B) placing the ceramic component in the chamber;
(C) drawing a vacuum in the chamber;
(D) filling the chamber with an inert gas to a pressure of a few millitorr;
(E) continuously providing vaporized metal in the chamber by feeding metal wire to a heating crucible to thereby vaporize the metal wire;
(F) forming a glow discharge around the ceramic component primarily by applying a negative bias voltage to a frame surrounding the ceramic component to ionize the inert gas within the chamber;
(G) ionizing the vaporized metal by passage of the metal through the ionized inert gas, and
(H) depositing on all surfaces of the ceramic component the ionized metal ions simultaneously from plural directions to thereby deposit the metal film uniformly on the ceramic component.

25. The method of claim 24 wherein the inert gas is argon.

26. The method of claim 24 wherein the metal is aluminum.

27. The method of claim 24 wherein the negative bias voltage applied to the frame is not greater than 4,000 volts.

28. The method of claim 26 wherein the negative bias voltage is applied until the aluminum film deposited on the ceramic component is 50 to 100 microns thick.

29. The method of claim 26 wherein the deposition rate of the aluminum film on the ceramic component is at least 50 angstroms per second.

30. The method of claim 20 wherein the negative bias voltage is approximately 2,000 volts and is applied for approximately four hours so that the aluminum film is deposited at a rate of at least 50 angstroms per second and achieves a thickness of 50 to 75 microns.
